(19) United States
(12) Patent Application Publication
(10) Pub. No.: US 2003/0049916 A1
(43) Pub. Date: Mar. 13, 2003

(54) Development of an intermediate-temperature buffer layer for the growth of high-quality GaxInyAlzN epitaxial layers by molecular beam epitaxy

(75) Inventors: Charles Surya, Kowloon (HK); Patrick Wai Keung Fong, Kowloon (HK)

Correspondence Address: JACKSON WALKER LLP, 112 E. Pecan Street Suite 2100, San Antonio, TX, 78205, US

(73) Assignee: The Hong Kong Polytechnic University, Kowloon (HK)

(21) Appl. No.: 09/931,856

(22) Filed: Aug. 20, 2001

(51) Int. Cl. H01L 21/20

(52) U.S. Cl. 438/478

(57) ABSTRACT

Gallium nitride and its related alloys have attracted much attention due to their important optoelectronic applications in blue to UV range as well as in the area of high-temperature electronics. Due to significant mismatches in the lattice constants and coefficients of thermal expansion between the GaN material and the sapphire substrate, GaN films typically exhibit large defect concentration and residual strain. In the present invention, a 20 nm thick low-temperature buffer layer is first grown on the sapphire substrate at preferably 500° C. This is followed by the growth of an intermediate-temperature GaN buffer layer (ITBL) at preferably 690° C. Finally, the epitaxial GaN layer is grown on top of the ITBL at preferably 750° C. It is found that the film quality is significantly affected by the use of an ITBL.

### BACKGROUND OF THE INVENTION

1. Field of the Invention

The present invention relates to the field of thin film semiconductors, and more specifically, to a method of improving the quality of a thin film which has poor lattice matching with the substrate onto which it is to be deposited.

2. Description of Prior Art

Gallium nitride and its related alloys have been under intense research in recent years due to their promising applications in optoelectronic devices, especially in the blue to UV range. Their large bandgap and high electron saturation velocity also make them excellent candidates for applications in high temperature and high-speed power electronics. Particular examples of potential optoelectronic devices include blue light emitting diodes, blue laser diodes, and UV photodetectors.

Common methods of deposition in the III-nitride family include hydride vapor phase epitaxy (HVPE), metalorganic chemical vapor deposition (MOCVD) and molecular beam epitaxy (MBE). To date, MOCVD and MBE are the most important growth techniques for GaN because they are capable of producing high quality heterojunctions. To date, GaN grown by MOCVD is generally superior to its counterpart grown by MBE. Nevertheless, MBE has shown to be an important growth technique for GaN thin films particularly for the fabrication of MODFETs (modulation doped field effect transistors) and high-speed solar blind UV detectors.

However, a current problem with the manufacture of GaN hin films is that there is no native substrate available, i.e. there is no readily available suitable substrate material which exhibits close lattice matching and close matching of thermal expansion coefficients. Presently, (0001) oriented sapphire is the most frequently used substrate for GaN epitaxial growth due to its low price, availability of large-area wafers with good crystallinity and stability at high temperatures. The lattice mismatch between GaN and sapphire is over 13%. Such huge mismatch in the lattice constants would cause poor crystal quality if GaN films were to be grown directly on the sapphire, due to stress formation and a high density of defects, including such defects as microtwins, stacking faults and deep-levels. Typically, these GaN thin films exhibit wide X-ray rocking curve, rough surface morphology, high intrinsic electron concentration and significant yellow luminescence. Another key parameter affecting the film quality is the III/V ration, and this has been studied extensively by Tarsa and co-workers.

A well known method of improving the crystal quality of epitaxial films in such strongly lattice mismatched systems is to deposit a thin buffer layer between the epilayer and the substrate at a relatively low temperature, providing a high density of nucleation centers. The AlN or GaN buffer layer serves to enhance two-dimensional growth and the density of nucleation for the epitaxial films. This is because the interfacial energy for the GaN/buffer system is found to be significantly lower than the GaN/sapphire system.

For example, using metal organic chemical vapor deposition (MOCVD), Kuznia et al, Akasaki et al, and Lee et al have found that an improvement in film quality occurs by the deposition of a thin low-temperature (LT) GaN or AlN buffer layer. In the molecular beam epitaxy (MBE) growth process, the implementation of a low temperature buffer layer has also proved beneficial to some extent. However, the mechanisms by which the buffer layer relieves stress, and by which the stress relaxation affects defect formation, are not well understood. Some groups reported an improved structural quality of MBE grown GaN on buffer layers, whereas others omitted the buffer layer without deteriorating the GaN epitaxial layer quality. This discrepancy and the lack of literatures reporting the effect of buffer layer on MBE grown GaN films raise an uncertainty on the effectiveness of LT GaN or AlN buffer layer system in MBE growth technology.

Recently, several groups have attempted to modify the LT buffer layer system. For example, Ohshima et al (J. Cryst. Growth 189/190, 275 (1998)) have experimented with the use of amorphous GaN buffer layers formed at room temperature and Kim et al (Mater. Res. Soc. Symp. Proc 622 T4.10 (2000)) have used a nitridation technique on a thin layer of Ga metal to form a GaN buffer layer by rf-MBE. Techniques for improving the electrical and optical properties of MBE grown GaN thin films include the following. In MBE, the nitrogen source is generally provided by ECR source, rf-plasma source or gaseous NH₃. Tang et al. reported that electron mobility, up to 560 cm ²V⁻¹s⁻¹, can be obtained using UHV magnetron sputtered AlN buffer layer and the epitaxial GaN layer was grown using NH₃ as the nitrogen source. High quality GaN was also grown using a GaN template deposited by migration enhanced epitaxy in conjunction with an AlN/GaN superlattice layer. A mobility of 668 cm²V⁻¹s⁻¹ was reported using this growth technique. Recently, Heying et al. reported the highest mobility to date of 1191 cm²V⁻¹s⁻¹ grown by rf-plasma assisted MBE on MOCVD-GaN/sapphire composite substrates. However, the optimal conditions for the growth of high quality GaN thin films have not yet been established.

In this invention, we provide a method of making a high quality crystalline film on a non-lattice matched substrate, comprising the steps of depositing a first buffer layer onto the substrate; depositing a second buffer layer on top of the first buffer layer; and depositing a crystalline film layer on top of the second buffer layer. Preferably, the second buffer layer is deposited at a higher temperature than the first buffer layer. Preferably, the second buffer layer is 100 nm to 1500 nm thick, and even more preferably, it is 600 nm to 1300 nm thick. The first buffer layer may be GaN, but more preferably is AlₓGa₁₋ₓN.

Improved optical and electronic properties can be accomplished when GaN films are grown on a novel double-buffer-layer structure. In a preferred embodiment of the invention, the double layer buffer structure consists of a 20 nm-thick AlₓGa₁₋ₓN first buffer layer deposited between 500° C. and 780° C. On top of this, an intermediate-temperature buffer layer (ITBL) was grown at 600° C. to 7200° C. It has been shown that both the electronic and optical properties of the top GaN epitaxial layers improved with the thickness of the ITBL with an optimal thickness of 800 nm. The observed improvements in the film quality are attributed to the relaxation of residual strain in the epitaxial layers.

The technique has been shown to substantially improve the electronic and optical properties of GaN epitaxial films. The optical and electrical properties were improved using a GaN first layer, but were further improved using a thin AlₓGa₁₋ₓN first layer. This will substantially improve the speed of the electronic devices and the internal quantum efficiency of optoelectronic devices being fabricated using this technique. Our studies also showed significant improvements in the crystallinity of the films by using this technique by lowering the defect concentration in the material leading to significant improvements in the noise properties of the films. This will have particularly important improvements in the application of UV detectors, in which noise is the major factor affecting the minimum detectable signal. Initial studies showed that the use of this technique leads to reduction in the noise power spectral density by nearly 4 orders of magnitude. This will have dramatic effects on the sensitivity of the UV detectors fabricated using this technique.

### SUMMARY OF THE INVENTION

It is an object to overcome or at least reduce these problems.

### BRIEF DESCRIPTION OF THE DRAWINGS

The present invention will now be described by way of example and with reference to the accompanying drawings, in which:

FIG. 1 is a (3×3) RHEED pattern of GaN grown on 800 nm ITBL upon cooling down below 200° C. with the electron beam along the [2\overline{11}0 ] direction.

FIG. 2 shows electron mobility and PL peak position at different intermediate-temperature buffer layer thickness, whereas the LT buffer layer kept constant at 20 nm.

FIG. 3 shows room temperature PL spectra of samples grown with various thickness of the intermediate-temperature buffer layer, whereas the LT buffer layer kept constant at 20 nm.

FIG. 4 shows the full-width-half maximum and the relative intensity of band edge emission peak of MBE-grown GaN films plotted against the thickness of the ITBL.

FIG. 5 shows room temperature electron mobilities and carrier concentration for samples A, B, C and D.

FIG. 6 shows typical photoreflectance spectra of MBE grown GaN films with and without ITBL.

FIG. 7 shows a two-layer noise model for GaN epitaxial layer on ITBL.

FIG. 8 shows room temperature voltage noise power spectral density of GaN thin films on various thicknesses of ITBLs. Sample A is indicated by a dashed line, sample B by squares, sample C by triangles, and sample D by circles. The solid line is a 1/f spectrum for visual comparison.

FIG. 9 shows voltage noise power spectra for sample A and sample C. Lines A1, A2 and A3 are voltage noise power spectra for sample A measured at T=103.6K, 108.4K and 113.2K respectively. Lines C1, C2 and C3 are voltage noise power spectra for sample C measured at T=96.9K, 100.7K and 104.4K respectively.

FIG. 10 shows Arrhenius plots of the fluctuation time constant, τ, for sample A (circle symbol) and sample C (square symbol).

FIG. 11 shows Hooge parameters measured from samples A, B, C and D.

FIG. 12 is a diagram of a UV detector.

### DESCRIPTION OF THE PREFERRED EMBODIMENT

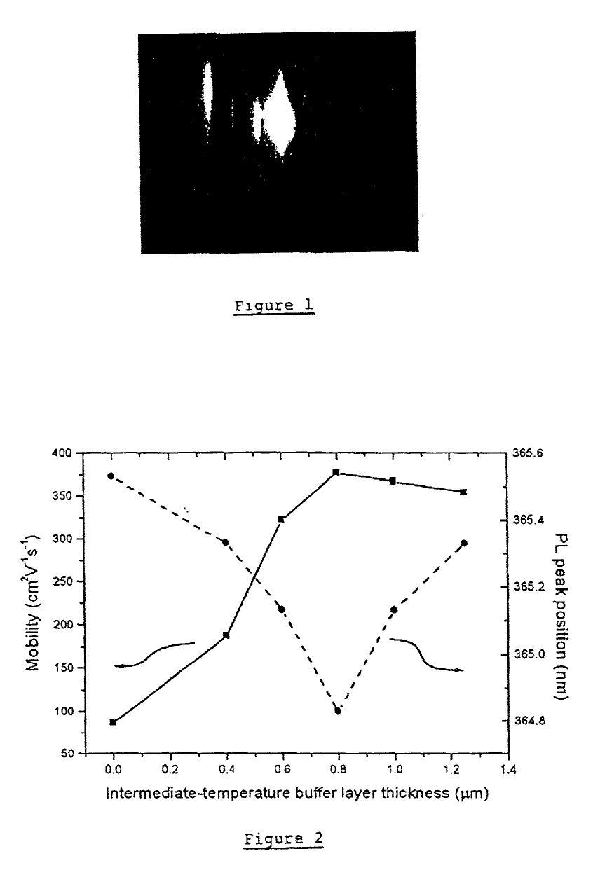

High quality silicon doped GaN epilayers were grown on (0001) sapphire substrates by rf-plasma assisted MBE equipped with an EPI UNI-Bulb nitrogen rf-plasma source. Substrate temperature was measured by a pyrometer, which was calibrated with the Al melting point. The sapphire substrates were degreased and cleaned using a standard cleaning procedure with organic solvents, followed by etching in 3H₂SO₄:1H₃PO₄ solution at 120° C. for 15 minutes, then being rinsed in de-ionized water and blown dry with nitrogen gas. The substrates were first outgassed in the growth chamber at 800-850° C. for 30 minutes. Nitridation was done at 500° C. for 20 minutes with a nitrogen flow rate of 1.0 sccm and a rf power of 500 W. Subsequently, 200 Å of an AlₓGa₁₋ₓN buffer layer was deposited at temperatures between 500° C. and 780° C. The substrate temperature was then raised to a temperature between 600° C. to 720° C. for the growth of the ITBL. The ITBL was grown under slightly Ga-rich condition, in which the plasma source was operated with a nitrogen flow rate of 1.0 sccm. Different thicknesses of ITBLs, varying from 400 nm to 1.25 μm, were grown on the conventional low-temperature buffer layer at 690° C. Finally, a slightly n-doped silicon-doped GaN epilayer was grown on top of the ITBL at 750° C. The thickness and carrier concentration of the Si doped GaN epilayer were 1.8 μm and 3×10¹⁷ cm⁻³, respectively. The surface morphology and optimal III/V ratio were monitored in-situ by reflection high-energy electron diffraction (RHEED) pattern. RHEED patterns of all the samples studied here exhibited pronounced (1×1) streak lines during growth. This suggested that the GaN surface is unreconstructed during growth. It is believed that the (1×1) unreconstructed surface is due to a monolayer of Ga which is tightly bound to the GaN. Upon cooling down below 300° C., (3×3) reconstructed RHEED patterns were observed which suggested that the GaN films grown on ITBL were N-face. In addition, the N-face characteristic is further confirmed by etching in molten KOH solution. A typical (3×3) RHEED pattern of GaN grown on 800-nm-thick ITBL is shown in FIG. 1.

To facilitate electrical measurements of GaN thin films, cross-bridge resistive structures were fabricated by hot KOH solution etching. This structure allows the characterization of I-V properties and the Hall mobility of the carriers. It also facilitates four-probe measurement of low-frequency noise over a wide range of temperatures. Ohmic contacts, with contact resistance less than 10⁻⁴ Ωcm², were fabricated by sputter deposition of Ti/Al bilayers. Well-behaved I-V characteristics for the devices were observed over the entire range of temperature at which the noise was investigated.

The optoelectronic properties of the GaN epitaxial layers were characterized by Hall and photoluminescence (PL) measurements. The room temperature Hall coefficient was measured by the Biorad HL5500 system. From the Hall coefficients the carrier concentrations for the various films were found to be around 3×10¹⁷ cm³. The electron mobilities for the films were also evaluated. The experimental results are shown in FIG. 2. Most interestingly, the electron mobility is found to increase steadily with the thickness of the ITBL. Typical mobility for films grown without an ITBL is 87 cm²V⁻¹s⁻¹ and the maximum mobility recorded for this series of samples is 377 cm²V⁻¹s⁻¹ for films grown with an ITBL thickness of 800 nm. Further increase in the ITBL thickness beyond 800 nm results in the gradual degradation in the mobility. For an ITBL thickness of 1.25 μm, the electron mobility is found to be 355 cm²V⁻¹s⁻¹. These Hall results demonstrated a mobility enhancement by a factor of 4.3 at RT when GaN films were grown on a 800-nm-thick ITBL compared to the one grown with identical growth conditions except without ITBL, for this particular series of samples. This significant improvement cannot be explained simply by the increase of the total thickness of the GaN films. As a control experiment, a GaN epilayer of thickness equal to 2.6 μm was grown without an ITBL, otherwise all other experimental conditions were identical to the films grown with ITBL. The mobility of the film was found to be 170 cm²V⁻¹s⁻¹. This clearly shows that ITBL plays a vital role in the improvement of the film quality.

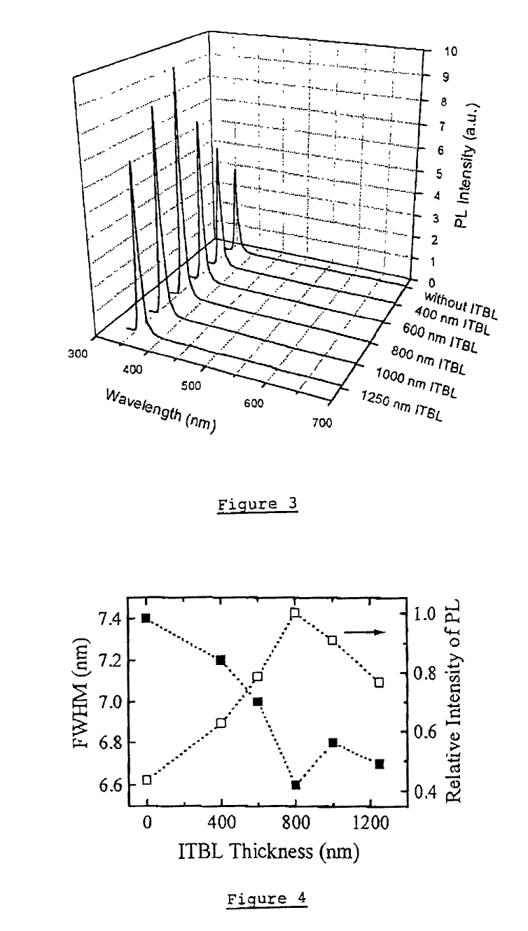

The PL also demonstrated systematic improvements with the is thickness of the ITBL. The room temperature PL of the films were characterized systematically. FIG. 2 also shows the dependence of PL peak position on ITBL thickness. Strong near band-edge emission at about 3.39 eV and no detectable yellow luminescence (YL) were observed for all samples, as shown in FIG. 3, showing that the samples are of high quality. More recent PL measurements show that the YL is over four orders of magnitude below the main peak. Detailed analyses of the PL spectra show that the magnitudes of the PL spectra also increase systematically, following the same trend as the mobility, as a function of the ITBL thickness. From Table 1 below, we observe that the magnitude of the PL spectrum for the film grown with an ITBL thickness of 800 nm is found to be increased by a factor of 2.3 compared to the films grown without an ITBL.

| | | | Near band |
|---|---|---|---|
| Thickness | | Normalized | edge peak |
| of ITBL | Hall mobility | PL | position |
| (nm) | μ (cm²V⁻¹s⁻¹) | intensity | λₚ (nm) |
| 0 | 82 | 0.44 | 367.2 |
| 400 | 187 | 0.62 | 367.0 |
| 600 | 322 | 0.79 | 366.8 |
| 800 | 377 | 1.00 | 366.5 |
| 1000 | 367 | 0.91 | 366.8 |
| 1250 | 355 | 0.77 | 367.0 |

In addition, it is noteworthy that the near band edge peak positions, λp, of the PL spectra are observed to vary systematically as well. The typical results are summarized in Table 1. From the data we observe that λp is 367.2 nm for the film grown without an ITBL. As the ITBL thickness increases, λp is found to decrease systematically. For an ITBL thickness of 800 nm, λp=366.5 nm. Further increase in the ITBL thickness leads to a rebound phenomenon in λp, and for an ITBL thickness of 1.25 μm λp=367.0 nm.

The FWHM (full width at half maximum) of the near band-edge luminescence is found to decrease steadily from 7.4 nm to 6.6 nm with an increase of the thickness of ITBL from 0 to 800 nm. A similar trend is observed with the PL magnitude. The results of the FWHM and magnitudes of the PL are shown in FIG. 4, in which the open squares represent the experimental data for the relative intensity of the PL spectra and the solid squares represent the results for the FWHM of the PL spectra. Further increase in the ITBL thickness beyond 800 nm results in the gradual increase in the FWHM and a FWHM of 6.7 nm is obtained for the sample grown with an ITBL of 1.25 μm thick. The photoluminescence (PL) results also demonstrate a systematic change in the intensity of the near band-edge emission, following the same trend as the electron mobility, as a function of the ITBL thickness which is clearly shown in FIG. 2. The correlated variations in the mobility and the PL spectra is indicative of a common mechanism behind both phenomena. The systematic shift in the peak position of the PL is attributed to the change in excitonic transition energies for the different GaN films. This results from the relaxation of residual strain in the epilayers due to the mismatches of lattice constants and coefficient of thermal expansion between sapphire and GaN. The peak energy of the PL increases steadily with the thickness of the IBTL, indicative of the relaxation of the residual tensile strain as ITBL thickness increases. The relaxation of residual strain within the material results in the improvement in the optoelectronic properties of the films. Our PL results show that the tensile stress relaxes with the application of an ITBL. However, for the ITBL thickness beyond 800 nm, both the electron mobility and the PL are seen to degrade slightly. This is associated with the rebound in the peak position of the PL, indicative of the increase in the residual strain for ITBL thickness larger than 800 nm, clearly indicating an optimal ITBL thickness of 800 nm.

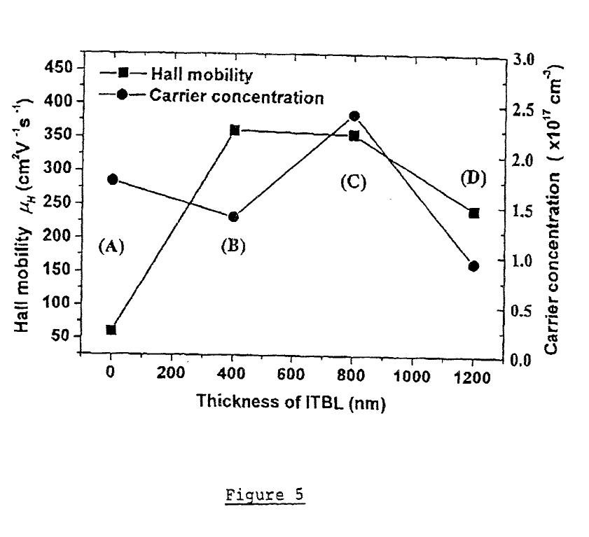

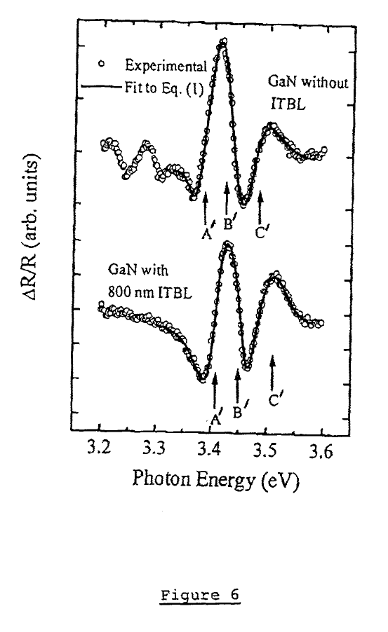

FIG. 5 shows the Hall mobility of another set of GaN thin films grown on various thicknesses of ITBLs, which exhibit similar variation in the electron mobility as the first set of samples. It is observed that a maximum value of about 360 cm²V⁻¹s⁻¹ is reached for an ITBL thickness between 400 nm and 800 nm. Further increase in the thickness of the ITBL beyond 800 nm results in the degradation in the Hall mobility. FIG. 5 also exhibits the carrier concentration of the samples as shown by the solid circles. The experimental results indicate that the carrier concentration remain relatively constant at about 1. 5×10¹⁷ cm⁻³.

Typical room temperature electron mobilities reported for ECR-MBE and rf-MBE were about 300 and 400 cm²V⁻¹s⁻¹, respectively. To the best of our knowledge the highest mobility reported so far using plasma assisted MBE growth technique is 668 cm²V⁻¹s⁻¹, which was accomplished by depositing the GaN epilayer on top of a superlattice and a 500 nm thick buffer layer grown by migration enhanced epitaxy. The advantage of our process is that the process is significantly simpler than migration enhanced epilayer technique. The Hall results of the series of samples shown in FIG. 2 were grown on a 20-nm-thick LT buffer layer. Initial results in our laboratory show that a maximum mobility of 430 cm²V⁻¹s⁻¹ can be obtained by varying the thickness of the low-temperature buffer layer while keeping the thickness of the ITBL at 800 nm. A systematic study is underway to confirm this point and to investigate the optimal conditions for the growth of the double buffer layer system. The mobility of 430 cm²V⁻¹s⁻¹ was obtained by using a 40 nm thick LT buffer layer.

The significant improvement in the carrier mobility is attributed to the reduction in threading dislocations. Due to the large lattice- and thermal-mismatches between GaN and sapphire substrate, a high density of threading dislocations in the range of 10¹⁰ to 10¹¹ cm⁻² is introduced into the GaN epilayers. As a result, electron mobility is reduced due to the enhanced probability of defect scattering. It has been shown that edge dislocations introduce acceptor centers along the dislocation lines, which capture electrons from the conduction band in an n-type semiconductor. The dislocation lines become negatively charged and a space charge is formed around it, which scatters electrons travelling across the dislocations and as a consequence, the electron mobility is reduced. For the film with a mobility of 430 cm²V⁻¹s⁻¹, the dislocation density is estimated to be 5×10⁹ cm⁻² according to the calculations by Ng et al. This value is comparable to those grown by migration enhanced epitaxy. Heying et al. demonstrated that x-ray rocking curves for off-axis reflections such as (102) plane is a reliable indicator of the threading dislocations in GaN thin films. However, x-ray analysis is not suitable in our case since the x-ray diffraction peak from the ITBL will overwhelm the full width half maximum of the measured rocking curve.

Photoreflectance (PR) was used to investigate the fine electronic band structure of GaN. The PR experiments are performed at room temperature. FIG. 6 shows the PR spectra of GaN films grown with and without an ITBL. To identify the origin and determine the energies for the observed optical transitions, the PR spectra are fitted to the low-field electroreflectance Lorentzian line shape functional form:

$$\frac{Δ R}{R} = Re [ {\sum }_{j = 1}^{n} \{ {C}_{j} {{ⅇ}^{{ⅈθ}_{j}} ( E - {E}_{j} + ⅈ {Γ}_{j} )}^{- {m}_{j}} \} ] , \qquad ( 1 )$$

where n is the number of the spectral function used in the fitting procedure, Cⱼ and □ⱼ are the amplitude and phase of the line shape, and Eⱼ and □ⱼ are the energy and the empirical broadening parameter of the transitions, respectively. The exponent mⱼ is a characteristic parameter, which equals 5/2 and 2 for three-dimensional interband transitions and excitonic transitions respectively. Excellent fitting with the experimental data, according to Eq. 1, can be made using mⱼ=2 and n=3 as shown in FIG. 2. These results suggest that the observed PR spectral features be of excitonic nature. The three excitons, referred to as A′, B′and C′ excitons, are related to the Γ₉^{V}-Γ₇^{C}, Γ₇^{V} (upper band)-Γ₇^{C} , and Γ₇^{V} (lower band)-Γ₇^{C} interband transitions of WZ GaN. For the sample with an 800 nm ITBL, E_{A}=3.41 eV. For the sample grown without ITBL, E_{A}=3.37 eV, which is substantially smaller than the other samples grown on top of ITBLs. The shift in the E_{A} shows that the tensile stress relaxes rapidly with the use of ITBL.

It is worth noticing that several minor peaks are observed in the PR for 3.2 eV<E<3.35 eV in the GaN film grown without the ITBL as indicated in FIG. 6. Similar phenomenon was reported by other groups, but did not give any detailed explanation regarding its origin. This feature is similar in characteristics to that observed in Ga₁₋ₓAlₓAs PR spectra, and was attributed to defects arising from impurities. Our results clearly show that such structures are eliminated in GaN films grown with ITBLs. Moreover, the empirical broadening parameter of the A′ exciton transition is about 60 meV for the sample grown without ITBL and 36 meV for the sample with an 800 nm ITBL. All these results show that the ITBL is useful for reducing defect density, which may be partly responsible for the observed improvements in the carrier mobility and PL spectra. The experimental results on electron mobility and PR are corroborated with the dependencies of the PL on the thickness of the ITBL. This implies that using a proper thickness of ITBL one can effectively improve the electronic and optical properties of GaN film grown by MBE through the relaxation of residual strain.

The change in excitonic transition energies for the different GaN films is attributed to the effects of residual strain in the epilayers due to the mismatches of lattice constants and coefficients of thermal expansion between GaN and the sapphire substrate. The strain-related phenomena in GaN epitaxial films have been well investigated both experimentally and theoretically. A number of authors have shown that the relaxation of the residual strain is associated with the shift in the PL and photoreflectance peak positions. Shikanai et al. reported that the energy of the free excitons associated with the top valence band varies linearly with the in-plane and the axial components of the strain tensor. These results indicate that the band structure of GaN is strongly influenced by the residual strain. The excitonic transition energy increases under compressive biaxial strain, and decreases under tensile biaxial strain. The small excitonic transition energy for the sample grown without ITBL indicates a large tensile stress existing in the film. Our PL results show that the tensile stress relaxes with the use of ITBL. The results agree well with previous report by Kisielowski et al., which is in contradiction to the results observed in MOCVD and HVPE grown GaN films, where the overall effects of strain generated in GaN is found to be compressive.

Studies on low-frequency noise have shown that the 1/f^{γ} noise in GaN thin films arises from crystalline defects. Measurements of low-frequency noise can, therefore, be utilized as a powerful tool for characterizing defect density in the material. In this paper, we report detailed experiment on the characterization of low-frequency excess noise in a series of GaN epitaxial films grown on various thicknesses of ITBLs. The results further elucidate the effects of ITBL on the defect density in the top epitaxial layers.

Flicker noise provides an important figure-of-merit for electronic and optoelectronic devices, and is increasingly being utilized as a characterizing tool for the quality of electron devices and materials. Studies of flicker noise in semiconductor devices have clearly shown that the noise arises from the capture and emission of free carriers by localized states in the material. Low-frequency noise is sensitive to traps at energy levels that are, typically beyond the range of conventional characterizing techniques such as deep-level transient spectroscopy. The noise power spectral density of the occupancy of the traps is given by the expression below

$$S ( f ) = 4 {\int }_{x} {\int }_{y} {\int }_{z} {\int }_{E} {N}_{T} ( x , y , z , E ) \frac{τ}{1 + {ω}^{2} {τ}^{2}} ⅆ x ⅆ y ⅆ z ⅆ E , \qquad ( 2 )$$

where N_{T} is the trap density in the material. Equation (2) stipulates that the noise power spectral density is directly proportional to the trap density.

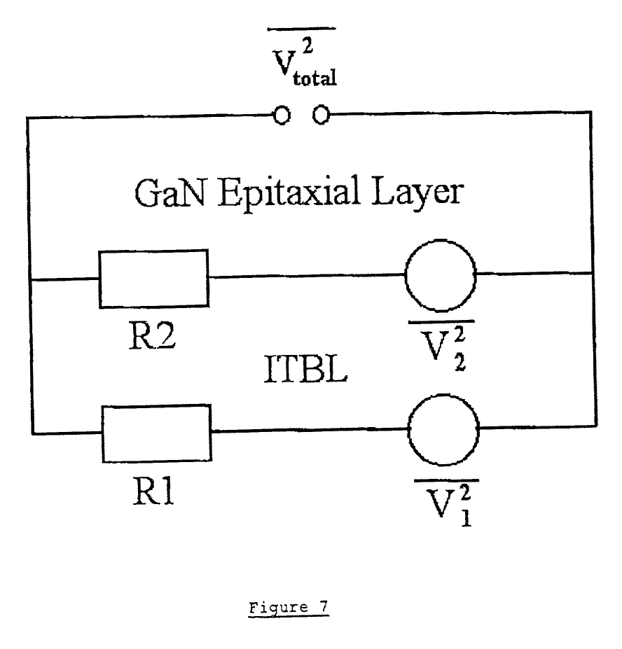

For convenience, we use the Hooge parameter, α, for comparing the magnitudes of flicker noise measured from the different samples fabricated at different experimental conditions, which is defined as

$$\frac{{S}_{V} ( f )}{{V}^{2}} = \frac{α}{fN} , \qquad ( 3 )$$

where N is the total number of free carriers. The Hooge parameter, α, is a convenient figure-of-merit for semiconductor materials. High quality materials are typically associated with small values of α. It is noted that our samples consist of two conducting layers, the ITBL layer and the epitaxial layer. This stipulates the use of a two-layer model for the analysis of the noise data as shown in FIG. 7. Each layer is modelled by an independent noise source in series with a resistor, where V₁ is the noise voltage for the ITBL, V₂ is the noise voltage for the epitaxial layer and Vₜₒₜₐₗ is the total noise voltage. The voltage noise power spectral density, resistance and the carrier concentration that accompanies the ITBL are determined experimentally from a single ITBL layer. The values are then used for the evaluation of the Hooge parameters of the top epitaxial layers of the samples. Assuming that V₁ and V₂ are independent of each other, principle of superposition can be applied in the determination of the total noise base on the following equation

$$\overline{{V}_{total}^{2}} = {( \frac{{R}_{1}}{{R}_{1} + {R}_{2}} )}^{2} \overline{{V}_{1}^{2}} + {( \frac{{R}_{2}}{{R}_{1} + {R}_{2}} )}^{2} \overline{{V}_{2}^{2}} . \qquad ( 4 )$$

To evaluate the Hooge parameters for the epitaxial layers, one needs to determine the carrier concentrations for the individual epitaxial layers as stipulated by the following expression:

$${n}_{2} = \frac{{( {μ}_{total} {n}_{total} - {μ}_{1} {n}_{S1} / d )}^{2}}{{μ}_{total}^{2} {n}_{total} - {μ}_{1}^{2} {n}_{S1} / d} , \qquad ( 5 )$$

where μₜₒₜₐₗ and nₜₒₜₐₗ are the overall mobility and carrier concentration, μ₁ and nₛ₁ are the Hall mobility and sheet carrier concentration of the ITBL alone, n₂ is the carrier concentration of the epitaxial layer and d is the total sample thickness.

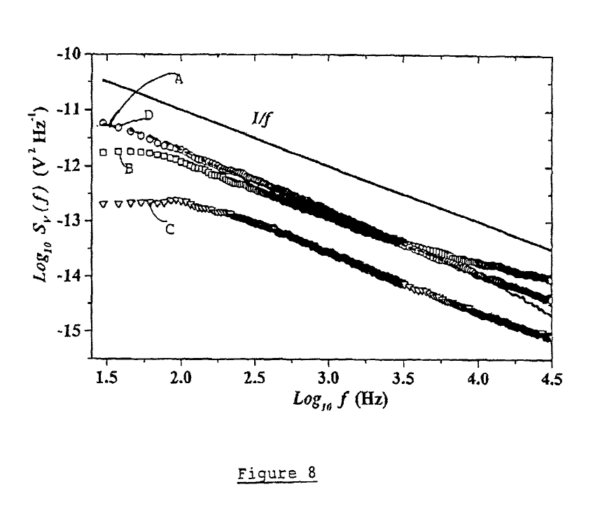

A separate set of GaN films were used for low frequency noise studies. Samples grown with ITBL thickness of 400 nm, 800 nm and 1.25 μm are denoted as samples B, C and D respectively. As a control sample, a GaN epilayer of thickness 2.6 μm was grown on the low-temperature buffer layer without an ITBL and will be referred to as sample A thereafter. Low-frequency noise was examined from room temperature to 90 K and over a frequency range of 30 Hz to 100 kHz. The fluctuating voltage was amplified by a PAR113 pre-amplifier and the voltage noise power spectra were measured by an HP3561A dynamic signal analyzer. Details of the noise measurement setup were given in previous reports. FIG. 8 shows typical voltage noise power spectra of GaN thin films grown on various thicknesses of ITBLs. The voltage noise power spectra measured from sample A are indictated by the dashed line. The voltage noise power spectra measured from sample B are indicated by the open squares. From the data we observe marginal reduction in noise level for sample B. Sample C, however, demonstrates a significantly lowered voltage noise power spectral density, as indicated by the open inverted triangles. Sample D, on the other hand, is seen to suffer from a large rebound in the flicker noise level, as shown by the open circles.

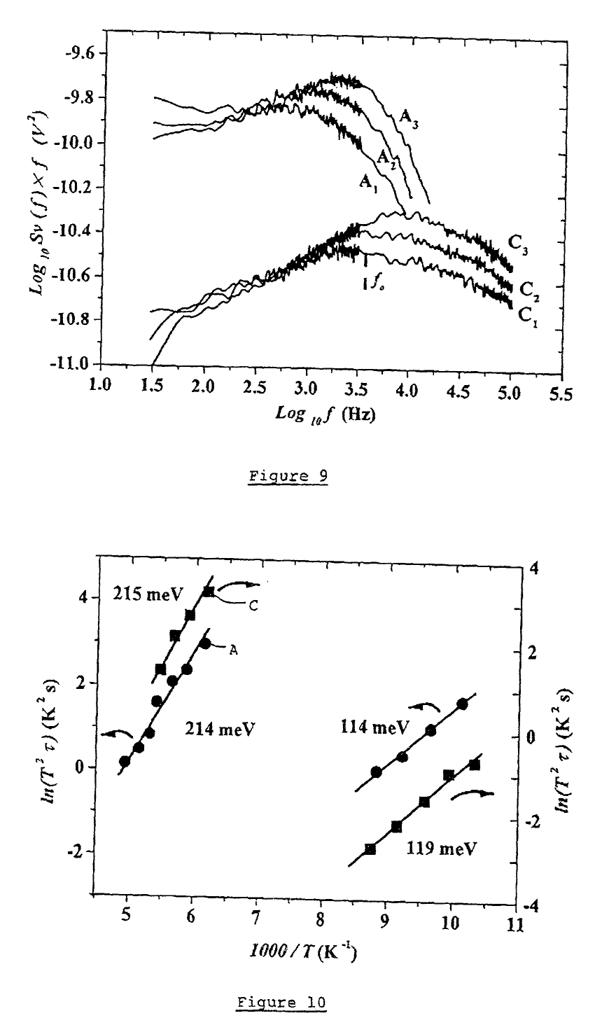

FIG. 9 shows experimental data on the voltage noise power spectra Log₁₀(Sᵥₓf) plotted as a function of the logarithm of the frequency, f, for a bias current of 0.04 mA. The experimental data indicates that fₒ systematically shifts towards higher frequencies as the device temperature increases. The thermal activation energy associated with each trap level can be determined from the Arrhenius plots of τ as shown in FIG. 10. The solid circles represent experimental data obtained from sample A and the solid squares represent experimental data measured from sample C. From the experimental data, Lorentzian bumps are observed superimposed with the 1/f^{γ} spectra. This is indicative of the presence of generation-recombination (G-R) noise in this frequency range. It is known that the cut-off frequencies of the Lorentzians, fₒ, are temperature dependent, from which the fluctuation time constants can be determined experimentally by τ=½_{π}fₒ. The G-R noise is modeled by thermally activated processes and the fluctuation time constant is given by τ=_{τo}exp(E_{τ/kT), where E}_{τ} is the trap thermal activation energy, which can be determined from the Arrhenius plot of τ. The results show that two different traps contribute to the G-R noise in the samples, with thermal activation energies of 114 meV and 214 meV for sample A. Sample C is found to exhibit similar activation energies for the G-R noise of 119 meV and 215 meV as shown in FIG. 10. The experimental results clearly show that using an ITBL does not alter the nature of the trap as indicated by the similar activation energies as found in samples A and C. However, we observe from FIG. 9 that there is a substantial reduction in the voltage noise power spectra for sample C, indicative of a corresponding reduction in the trap density. These experimental results on the low-frequency noise show that the quality of the top epitaxial layer is strongly affected by the thickness of the underlying ITBL, with an optimal thickness of 800 nm. The results clearly demonstrate the beneficial effects of ITBL on the properties of low-frequency noise in GaN epitaxial thin films.

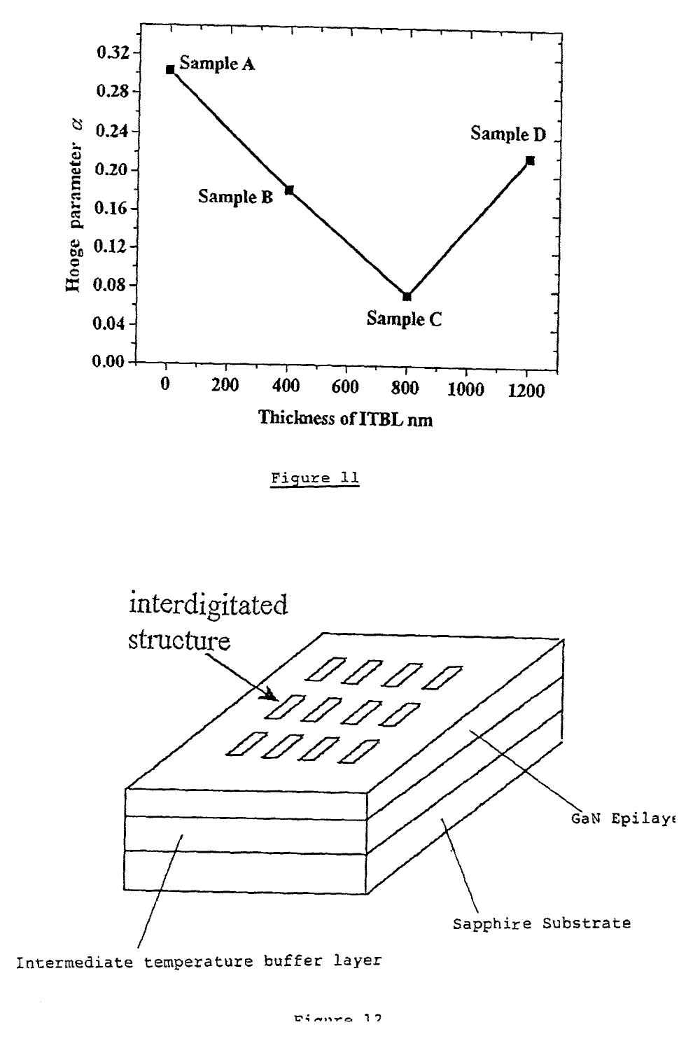

The Hooge parameters determined for the epitaxial layers of our samples are shown in FIG. 11, which exhibit steady decrease with the increase in the thickness of the ITBL. A minimum value of 7.34×10⁻² is reached for sample C. Upon further increase in the thickness of the ITBL, we observe a degradation in the Hooge parameter as seen in FIG. 11.

The systematic change in the Hooge parameters measured from our devices follows the same trend as the PL peak. Some reports have shown that the residual strain affects the energy band structure resulting in a shift in the excitonic transition energy of the material. Our experimental results strongly indicate that the observed reduction in defect density and the corresponding improvements in Hooge parameters for the GaN epitaxial thin films are attributed to the relaxation in the residual strain.

In summary, systematic investigations on the effects of the thickness of the intermediate-temperature buffer layer on the electrical, optical, and structural properties of GaN thin films grown by rf-plasma MBE on (0001) sapphire substrates have been conducted. The intermediate-temperature buffer layer was first grown on top of an AlₓGa₁₋ₓN buffer layer before the deposition of the GaN epilayers. The thickness of the intermediate-temperature buffer layers were systematically varied up to 1.25 μm. The electron mobility is found to improve with the thickness of the intermediate-temperature buffer layer, which peaks at 377 cm²V⁻¹s⁻¹ for a thickness of 800 nm for the intermediate-temperature buffer layer. Further increase in the thickness of the intermediate-temperature buffer layer results in the gradual degradation in the electron mobility. We speculate that the electron mobility enhancement is attributed to the residual strain relaxation by means of the intermediate-temperature buffer layer, which leads to the reduction of dislocations in the material. The photoluminescence also indicated a systematic increase in the intensity as well as a reduction in the full-width-half-maximum with the use of ITBL. The PL spectra are found to follow the same trend as the electron mobility. In addition, we observe a systematic shift in the peak position of the PL as a function of the intermediate-temperature buffer layer thickness with a trend that corroborates the variation of the electron mobility. The PR measurements suggest that the improvements in the film quality may originate from the relaxation of the residual strain within the material. Systematic investigation of low-frequency noise have shown that the utilization of an intermediate-temperature buffer layer (ITBL) in the growth of GaN epitaxial layers have led to significant improvements in the Hooge parameters.

The method of the invention has been used in the fabrication of a UV detector in FIG. 11. The UV detector was made by deposition of a thin layer of Pt (or Au) onto an epitaxial GaN layer. The thickness of the metallic layer is about 100 nm thick. Interdigitated structures were fabricated either by wet etching or lift-off technique. The typical width of the interdigitated fingers is about 5 μm wide. Such a structure constitutes a pair of back-to-back Schottky diodes. Under normal operation, a voltage bias of about 2 to 4 V will be applied across the interdigitated fingers. Photons impinging on the GaN between the fingers will cause electron-hole pairs to be generated. The carriers will then be collected by the metallic contacts. In our devices, the epitaxial GaN film was deposited on a double buffer structure consisting of an AlₓGa^{1-x}N buffer layer of thickness approximately 20 nm and an intermediate temperature buffer layer of thickness roughly 800 nm.

I claim:

1. A method of making a high quality crystalline film on a non-lattice matched substrate, comprising the steps of:
depositing a first buffer layer onto the substrate,
depositing a second buffer layer on top of the first buffer layer, and
depositing a crystalline film layer on top of the second buffer layer.

2. A method as claimed in claim 1, wherein the second buffer layer deposition temperature is different from the first buffer layer deposition temperature.

3. A method as claimed in claim 1 or claim 2, wherein the first buffer layer is AlₓGa₁₋ₓN and the second buffer layer is gallium nitride.

4. A method as claimed in any one of claims 1 to 3, wherein the crystalline film is AlₓIn_{y}Ga_{(1-x-y)}N.

5. A method as claimed in any one of claims 1 to 4, wherein the substrate is sapphire.

6. A method, as claimed in any one of claims 1 to 5, wherein the first buffer layer is 10 to 50 nm thick.

7. A method, as claimed in any one of claims 1 to 6, wherein the second buffer layer is 100 nm to 1500 nm thick.

8. A method as claimed in any one of claims 1 to 7, wherein the first buffer layer deposition temperature is 400° C. to 780° C.

9. A method as claimed in any one of claims 1 to 8, wherein the second buffer layer deposition temperature is 600° C. to 730° C.

10. A method as claimed in any one of claims 1 to 9, wherein the film deposition temperature is 730° C. to 800° C.

11. A high quality crystalline film, deposited onto a substrate via a double layer buffer, wherein the two layers of the buffer reduce the strain between the film and its substrate.

12. A double layer buffer for matching and reducing strain between a crystalline film and its substrate.

13. A semiconductor device made according to a process comprising the method described in any one of claims 1 to 10.
